(19) United States
(12) Patent Application Publication
(10) Pub. No.: US 2006/0203735 A1
(43) Pub. Date: Sep. 14, 2006

(54) Bridge apparatus and control packet processing apparatus in a spanning tree protocol network

(75) Inventors: Kou Takatori, Kawasaki (JP); Yasushi Sasagawa, Kawasaki (JP); Masami Doukai, Kawasaki (JP)

Correspondence Address: BINGHAM MCCUTCHEN LLP, 3000 K STREET, NW, BOX IP, WASHINGTON, DC, 20007, US

(73) Assignee: FUJITSU LIMITED

(21) Appl. No.: 11/168,366

(22) Filed: Jun. 29, 2005

(30) Foreign Application Priority Data
Mar. 14, 2005 (JP) 2005-071372

(51) Int. Cl. H04L 12/28; G01R 31/08; G08C 15/00; H04L 12/26; G06F 11/00; H04J 3/14; H04J 1/16; H04L 1/00; H04L 12/56

(52) U.S. Cl. 370/242; 370/256; 370/401; 370/216

(57) ABSTRACT

A bridge apparatus, which enables communications to continue even if a fault or a disability of operation occurs, causing the spanning tree protocol to become inoperable and, furthermore, provides a network capable of keeping track of status changes thereof, are provided by a bridge apparatus constituting a network connected with other bridge apparatus, comprising an STP protocol processing unit for carrying out a spanning tree protocol; a port for transmitting and receiving a bridge protocol data unit with the other bridge apparatus; a fault detection unit for detecting a fault of the spanning tree protocol by monitoring the STP protocol processing unit; and a for-fault time BPDU transmission unit for transmitting a for-fault time bridge protocol data unit to the other bridge apparatus by way of the port if the fault detection unit detects a fault, or a disability of operation, of the spanning tree protocol.

### BACKGROUND OF THE INVENTION

1. Field of the Invention

The present invention relates to a bridge apparatus and control packet processing method for processing a control packet transmitted and received between bridge apparatuses which support a Spanning Tree Protocol (STP)

2. Description of the Related Art

The spanning tree protocol is a protocol making it possible to uniquely determine a frame relay path between bridge apparatuses by blocking data frame relay by way of a specific port in the case where there are physically redundant routes (i.e., no less than two routes) between random bridge apparatuses in a network, which is standardized as IEEE (Institute of Electrical and Electronic Engineers) 802.1D, Media Access Control (MAC) Bridges.

Specifically, one bridge apparatus is first determined as a root by transmitting and receiving a control packet which is called a Bridge Protocol Data Unit (BPDU) in a network comprising a plurality of bridge apparatuses. Each bridge apparatus has a 64-bit Bridge ID comprising a 16-bit Bridge Priority whose setting is changeable and a 48-bit MAC address assigned to each bridge apparatus. The bridge apparatus having the smallest Bridge ID will be established as the root bridge apparatus by storing a Bridge ID in the BPDU followed by transmitting and receiving it between adjacent bridge apparatuses.

The establishment of the root bridge apparatus is followed by setting up paths like a tree starting from the root bridge apparatus and inhibiting data from traveling (i.e., blocking) other paths (i.e., links) other than the tree-like paths, thereby enabling a path to be determined uniquely between discretionary bridge apparatuses. If there is a possibility of two or more paths existing between discretionary bridge apparatuses, the final path is determined by calculating a cost of entire path based on a cost vis-à-vis a link speed of the link connecting adjacent bridge apparatuses (cost decreases with link speed, usually) and blocking paths other than the one with the lowest cost.

After determining a tree-like path, the BPDU is periodically sent from the root bridge apparatus in the direction of leafs in a tree like path. The BPDU is sent periodically and the interval between sending BPDUs is called the Hello Time, with the default interval being commonly set at two seconds.

FIG. 1A exemplifies BPDU transmission and reception between bridge apparatuses in a normal state.

In FIG. 1A, a network 10 comprises bridge apparatuses 11, 21, 31 and 41, with the bridge apparatus 11 being assigned as the root bridge apparatus. And a port 43 of the bridge apparatus 41 corresponding to a port (i.e., designated port) 33 of the bridge apparatus 31 is blocked as an alternate port.

In the network 10 comprised as described above, a BPDU is transmitted from ports (i.e., designated ports) 12 and 13 of the bridge apparatus 11 to the other bridge apparatuses 21, 31 and 41 sequentially in the direction of the arrows (i.e., direction of leafs) . That is, the BPDU transmitted from the port (i.e., designated port) 12 of the bridge apparatus 11 is received by the port (i.e., root port) 22 of the bridge apparatus 21, and the BPDU transmitted from the port (i.e., designated port) 13 of the bridge apparatus 11 is received by the port (i.e., root port) 32 of the bridge apparatus 31. And, the BPDU sent out from the port (i.e., designated port) 23 of the bridge apparatus 21 is received by the port (i.e., root port) 42 of the bridge apparatus 41.

In this setup, if the bridge apparatus 21 becomes disabled from continuing an operation of spanning tree protocol due to a software fault or disability of operation, a bug occurrence, a software update, etcetera, normal transmission/reception of BPDUs becomes impossible between the adjacent bridge apparatuses 11 and 41. As a result, it becomes impossible to decide accurately on a place to block (i.e., port 43) in the network 10, hence bringing about a possibility of forming a loop in the network 10. A common method to avoid the forming of a loop is to have the bridge apparatus 21, in which a fault or inability of operation has occurred, shutdown port operation (i.e., link-down of port, or blocking a data frame) forcibly.

Meanwhile, there is a disclosed technique for keeping a topology unchanged even when adding apparatus to a network for connecting segments such as a router, a bridge or a switching hub for a LAN, or when restarting an operation within a network achieved by only receiving BPDU messages from each port, instead of transmitting BPDU messages from such an apparatus (added or restarted) for a certain period of time, and assigning a Bridge ID to such an apparatus with a value being larger than any Bridge IDs contained in the received BPDU messages: e.g., refer to laid-open Japanese patent application publication No. 2002-330152.

A redundantly comprised network by supporting the spanning tree protocol, however, has been faced with a problem that, if the spanning tree protocol becomes inoperable in a random bridge apparatus, hence requiring a port of the aforementioned bridge apparatus to block, an entirety of communication through the bridge apparatus is disabled as a result. This problem occurs not only at a fault occurrence or disability of operation such as the spanning tree protocol becoming inoperable but also at an update of the software on which the spanning tree protocol operates.

In order to solve the problem, a technique has been conceived (i.e., Japanese patent application No. 2003-431154 applied for by the applying entity of the present invention; “related application” hereinafter) for enabling continuous operation of a port by making the hardware transmit the same BPDU as the one being transmitted up to the present, and continue to do so, if the operation of the spanning tree protocol becomes disabled.

The problem with the above technique is that it is not possible to keep track of changes if a change of configuration, a fault or a disability of operation occurs in the network in the interim, since the same BPDU as that when the spanning tree protocol operated normally is repeatedly sent in a fixed manner (i.e., hardware-wise).

### SUMMARY OF THE INVENTION

In consideration of the above described circumstances, the purpose of the present invention is to provide a bridge apparatus, and a control packet processing method, enabling communication to continue if a fault or a disability of operation occurs to disable a spanning tree protocol and enabling tracking of changes in the network state thereafter.

In order to solve the above described challenge, the present invention has adopted a comprisal as described in the following.

That is, in an aspect of the present invention, a bridge apparatus according to the present invention, being the bridge apparatus constituting a network by connecting with other bridge apparatus, comprises an STP protocol processing unit for carrying out a spanning tree protocol; a port for transmitting and receiving a bridge protocol data unit with the other bridge apparatus; a fault detection unit for detecting a fault, or a disability of operation, of the spanning tree protocol by monitoring the STP protocol processing unit; and a for-fault time BPDU transmission unit for transmitting a for-fault time bridge protocol data unit to the other bridge apparatus by way of the port if the fault detection unit detects a fault, or a disability of operation, of the spanning tree protocol.

Also, in a bridge apparatus according to the present invention, a for-fault time bridge protocol data unit transmitted by the for-fault time BPDU transmission unit preferably has a smaller valued route identifier than a route identifier possessed by the other bridge apparatus.

Also, in a bridge apparatus according to the present invention, the for-fault time BPDU transmission unit preferably transmits the for-fault time bridge protocol data unit to the other bridge apparatus by way of all ports in a state of forwarding.

Also, in a bridge apparatus according to the present invention, the for-fault time BPDU transmission unit preferably transmits the for-fault time bridge protocol data unit to the other bridge apparatus by way of all ports, and the ports preferably reset a state of non-forwarding to a state of forwarding.

In another aspect of the present invention, a control packet processing method according to the present invention, carried out by a bridge apparatus comprising an STP protocol processing unit for carrying out a spanning tree protocol, and a port for transmitting and receiving a bridge protocol data unit with another bridge apparatus; and constituting a network by connecting with another bridge apparatus, comprising the steps of detecting a fault, or a disability of operation, of the spanning tree protocol by monitoring the STP protocol processing unit; and transmitting a for-fault time bridge protocol data unit to the other bridge apparatus by way of the port if detecting a fault, or a disability of operation, of the spanning tree protocol.

### BRIEF DESCRIPTION OF THE DRAWINGS

FIG. 1A exemplifies BPDU transmission and reception between bridge apparatuses in a normal state;

FIG. 1B exemplifies a BPDU format;

FIG. 2A exemplifies a restructuring of topology when a bridge apparatus 21 is at fault (part 1);

FIG. 2B exemplifies a restructuring of topology when a bridge apparatus 21 is at fault (part 2);

FIG. 3 shows a comprisal of a bridge apparatus applied by the present invention;

FIG. 4 exemplifies a configuration of a MAC learning table;

FIG. 5 exemplifies a restructuring of topology when a bridge apparatus 41 is at fault (part 1);

FIG. 6 exemplifies a restructuring of topology when a bridge apparatus 41 is at fault (part 2);

FIG. 7 exemplifies a restructuring of topology when a bridge apparatus 41 is at fault (part 3);

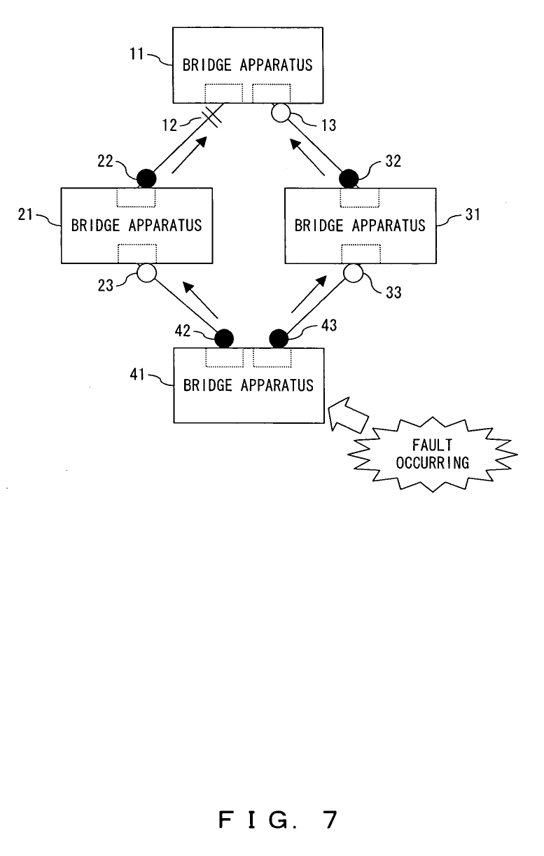

FIG. 8 shows a comprisal of a bridge apparatus of a first embodiment applied by the present invention;

FIG. 9 shows a processing sequence from fault, or disability of operation, to recovery in the apparatus itself;

FIG. 10 shows a processing sequence from fault, or disability of operation, to recovery in an external apparatus;

FIG. 11 shows a configuration of bridge apparatus according to the present invention; and

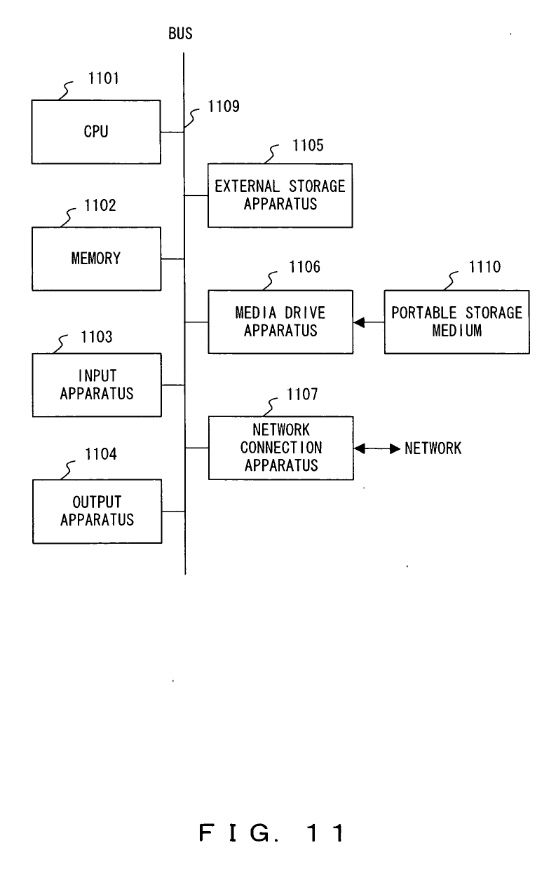

FIG. 12 describes loading of the control packet processing program according to the present invention into a computer.

### DESCRIPTION OF THE PREFERRED EMBODIMENTS

Let the following describe the application of the preferred embodiment of the present invention while referring to the accompanying drawings.

The first description is of an overview of the present invention.

The characteristic of the present invention, in a network constituted by interconnecting a plurality of bridge apparatuses which support the spanning tree protocol, when the spanning tree protocol becomes inoperable in a certain bridge apparatus due to the occurrence of a fault, or a disability of operation, or a software update, is to restructure the network by transmitting a BPDU having a minimum valued Root ID from the aforementioned bridge apparatus.

Note that a bridge apparatus is an apparatus for receiving an Ethernet® frame, determining a suitable addressee port according to an addressee MAC address within the frame and transmitting the received frame.

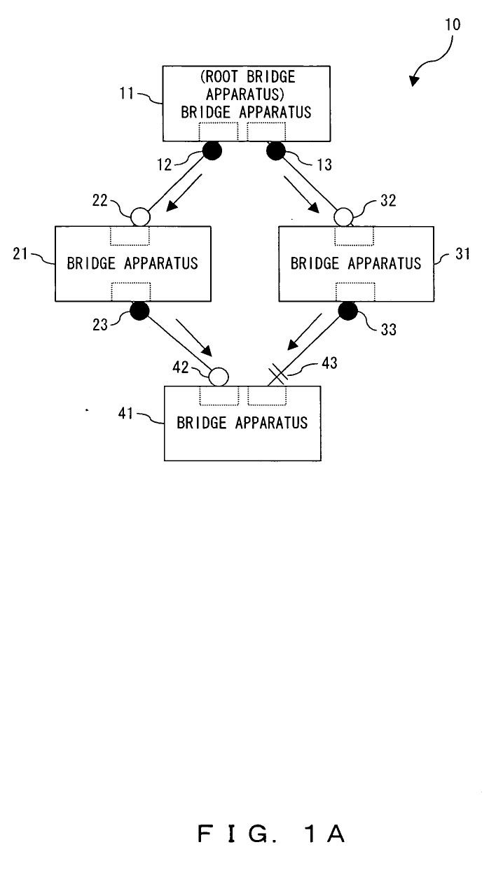

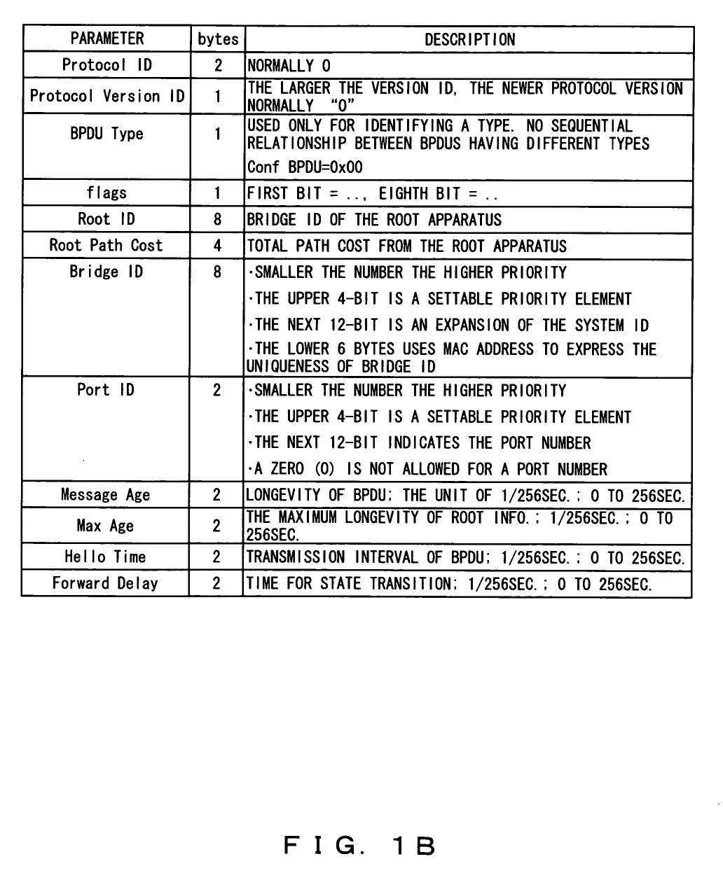

The first description is of an outline of operation of the spanning tree protocol with FIG. 1A taken as an example.

FIG. 1A exemplifies a BPDU transmission and reception between bridge apparatuses in a normal state. And, FIG. 1B exemplifies a BPDU format.

In FIG. 1A, shortly after each bridge apparatus 11, 21, 31 and 41 start up, the state is that each bridge apparatus, the bridge apparatus 11 for example has not received a BPDU either from the bridge apparatus 21 or 31, and therefore the bridge apparatus 11 recognizes that it is the root bridge apparatus and accordingly transmits the BPDU (refer to FIG. 1B) of “Bridge ID field (containing a priority and its own MAC address)” and of “Root ID field (containing its own bridge ID)” periodically to the adjacent bridge apparatuses 21 and 31. Having received the BPDU, the bridge apparatus 21 or 31 compares the Bridge ID which is set in the Root ID field of the received BPDU with that of its own (i.e., bridge apparatuses 21 or 31), recognizes the one having a smaller value (e.g., bridge apparatus 11) as the root bridge apparatus) and periodically transmits a BPDU with a Root ID field value which is set to a smaller value than the currently recognized root bridge apparatus 11 in the remote direction.

A root bridge apparatus (e.g., bridge apparatus 11) having the smallest Bridge ID in the network 10 is recognized among all the bridge apparatuses 11, 21, 31 and 41 by performing the above described operation between all adjacent bridge apparatuses 11, 21, 31 and 41. Meanwhile, the BPDU propagates not only root bridge information but also cost (i.e., distance) information from the root bridge apparatus (e.g., bridge apparatus 11), thereby making it possible to recognize the distance from the port of each of the bridge apparatus 11, 21, 31 and 41 to the root bridge apparatus (e.g., bridge apparatus 11) and judge as to which port to block.

In the example shown by FIG. 1A, the fact that the bridge apparatus 11 has the smallest Bridge ID and thus that the bridge apparatus 11 is the root bridge apparatus 11 of the bridge apparatuses 11, 21,31 and 41 is recognized by the BPDU which is transmitted every two seconds from the root bridge apparatus 11 as the origin.

Here, even if the bridge apparatus 11 as the root bridge apparatus 11 receives a BPDU from the adjacent bridge apparatuses 21, 31 or from bridge apparatus 41, if the BPDU does not have a Root ID which is smaller than its Bridge ID, then it is unnecessary to change the network topology (i.e., by blocking of its own port (i.e., bridge apparatus 11), or un-blocking of it), or by reflecting in the BPDU value it transmits (i.e., bridge apparatus 11) by using the information in the received BPDU.

The present invention utilizes the above described characteristic of the root bridge apparatus constituting a spanning tree protocol network, that is, the characteristic that receiving a BPDU becomes unnecessary.

In FIG. 1A, let it be assumed that a spanning tree protocol has become inoperable due to a fault or a disability of operation in the bridge apparatus 21. In this case, the port (i.e., root port) 22 and port (i.e., designated port) 23 will be blocked in the conventional technique. Meanwhile, the port (i.e., designated port) 23 will be made to continue to transmit the same BPDU as the one having been transmitted up to now autonomously hardware-wise according to the above noted related patent application.

In the former method, communications of the bridge apparatus 21 with the other bridge apparatuses 11, 31 and 41 become disabled. In the latter method, although communication can continue, it is not possible to cope with a case in which a setup change, a fault or a disability of operation occurs in the other bridge apparatuses 11, 31 or 41, at a later time, causing a change in the BPDU received by the bridge apparatus 21 or the BPDU to be transmitted therefrom and bringing forth a risk of forming a loop in the network 10.

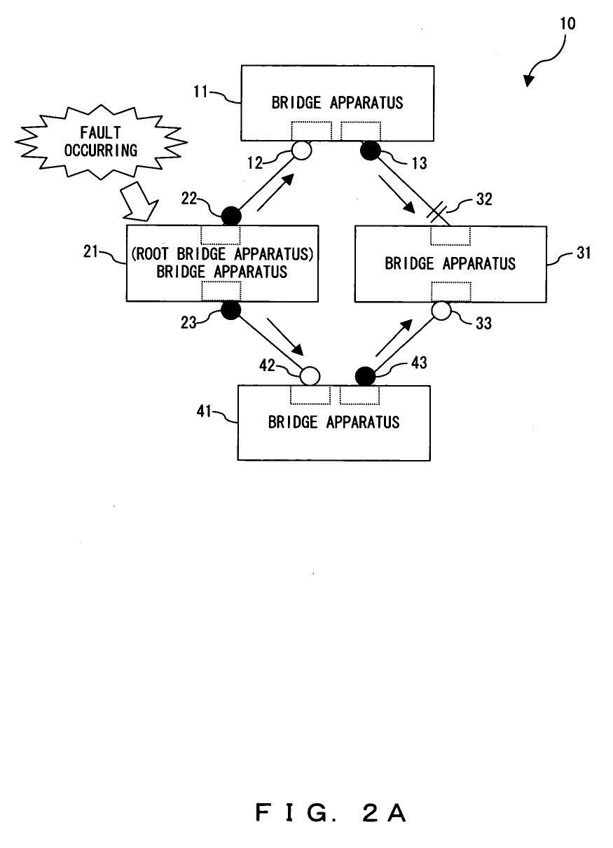

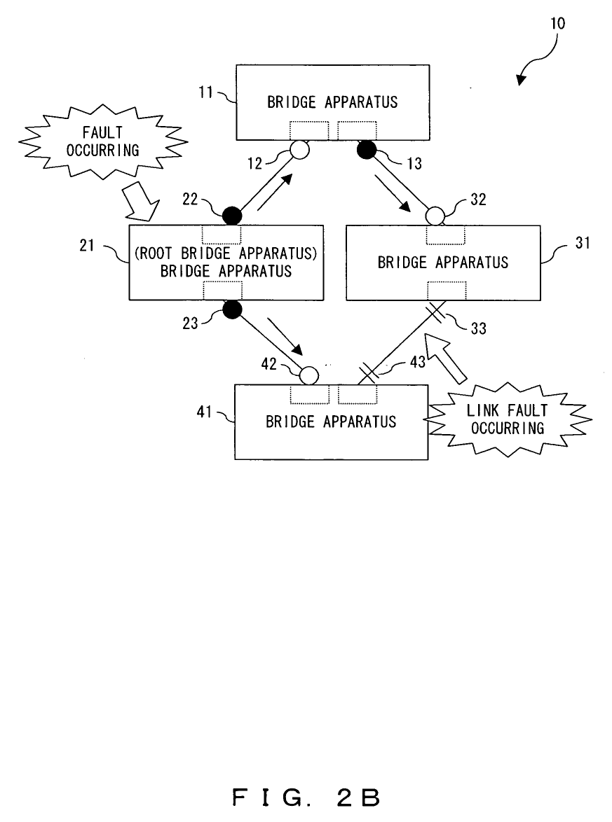

Here, the present invention is capable of restructuring a topology with the bridge apparatus 21 as the root bridge apparatus as shown by FIG. 2A by making the bridge apparatus 21 transmit a BPDU having a Root ID field of the smallest value (e.g., zero (0)) within the network 10 to the adjacent bridge apparatuses 11 and 41 forcibly when the spanning tree protocol becomes inoperable in the bridge apparatus 21. Note that the same value as the Root ID is preferably set for the Bridge ID field of the transmitting BPDU.

That is, in FIG. 2A, if the spanning tree protocol becomes inoperable due to a fault or a disability of operation in the bridge apparatus 21, the bridge apparatus 21 recognizes itself as the root bridge apparatus and periodically transmits a BPDU of “Bridge ID field (e.g., zero)” and “Root ID field (including Bridge ID =0, for itself)”, that is, the BPDU with the Root ID as a root identifier becoming the smallest within the network of adjacent bridge apparatuses 11 and 41. Having received the BPDU, the bridge apparatuses 11 and 41 respectively compare the Bridge ID=0, which is set in the Root ID field of the received BPDU, with their own Bridge IDs (i.e., bridge apparatus 11 or 41), recognizes a bridge apparatus having a smaller value (i.e., bridge apparatus 21 having “zero”) as the root bridge apparatus, and periodically transmits a BPDU with the smaller number (i.e., zero) being set for the Root ID field from the currently recognized root bridge apparatus (i.e., bridge apparatus 21) in the remote direction.

By repeating the above described operations between all the adjacent among the bridge apparatuses 11, 21, 31 and 41, all the bridge apparatuses 11, 21, 31 and 41 recognize that the bridge apparatus 21 having the smallest Bridge ID (i.e., zero (0)) within the network 10 as the root bridge apparatus for the spanning tree protocol.

And each apparatus will join in the tree formation paths according to the spanning tree protocol with the root bridge apparatus 21 as the root.

Meanwhile, assuming the state shown by FIG. 2A, if a link fault occurs between the bridge apparatuses 31 and 41 for instance as shown by FIG. 2B, an operation of switching the paths functions is normally performed by the spanning tree protocol, thereby enabling the communication to continue.

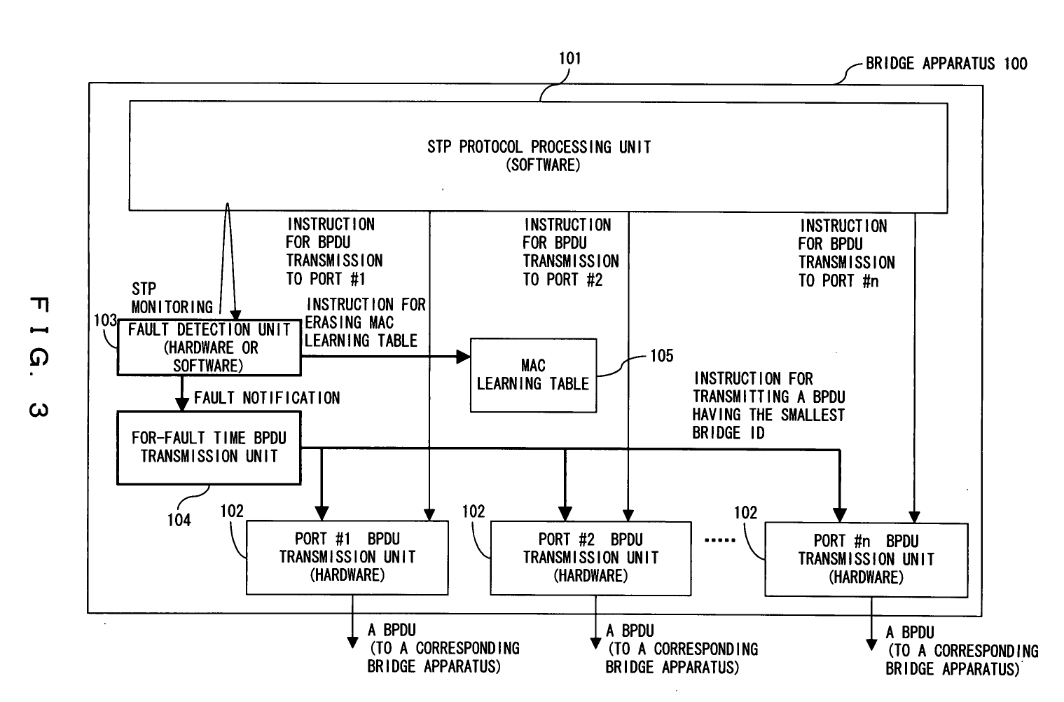

FIG. 3 shows a comprisal of a bridge apparatus to which the present invention has been applied.

In FIG. 3, the bridge apparatus 100 comprises an STP protocol processing unit 101 for carrying out a spanning tree protocol by software; a plurality of BPDU transmission units (i.e., ports) 102 for transmitting a BPDU to each of the other bridge apparatus; a fault detection unit 103 for detecting a fault, or a disability of operation; a for-fault time BPDU transmission unit 104 for transmitting a for-fault time BPDU to the other bridge apparatuses by way of BPDU transmission units (i.e., ports) 102 if the fault detection unit detects a fault, or a disability of operation; and a MAC learning table 105.

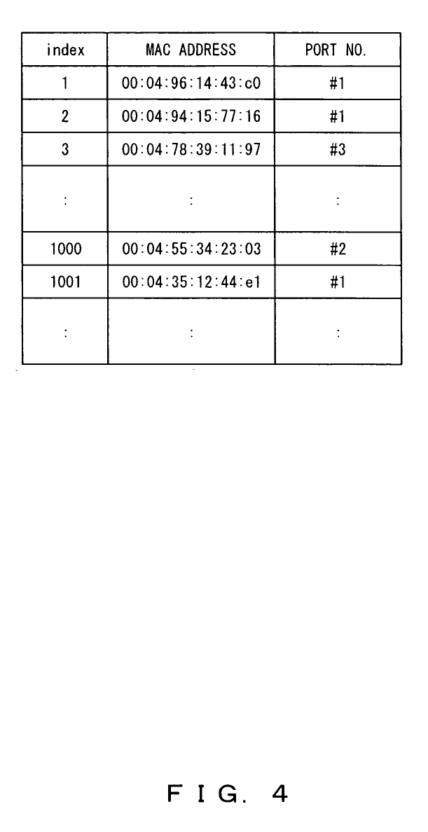

FIG. 4 exemplifies a configuration of a MAC learning table.

When inputting a frame, a source (i.e., transmitter) MAC address for the input frame and a port number for the input port are recorded in the MAC learning table as a set.

And, when outputting a frame, an existence of destination (i.e., addressee) MAC address for the output frame is searched in the MAC learning table and, if existing, the frame will be transmitted to the port of a port number corresponding to the MAC address. Conversely, if not existing, the frame is transmitted from each of every port in the state of forwarding, other than the input ports.

Returning to the description of FIG. 3.

If the spanning tree protocol becomes inoperable in a certain bridge apparatus 100 due to a software fault, a disability of operation, a bug occurrence, a software update, et cetera, in the case of forming a network by interconnecting a plurality of such configured bridge apparatuses 100, then the fault detection unit 103 detects the fault or the disability of operation, and the for-fault time BPDU transmission unit 104 transmits a for-fault time BPDU containing the Bridge ID=0 to each of the other bridge apparatuses.

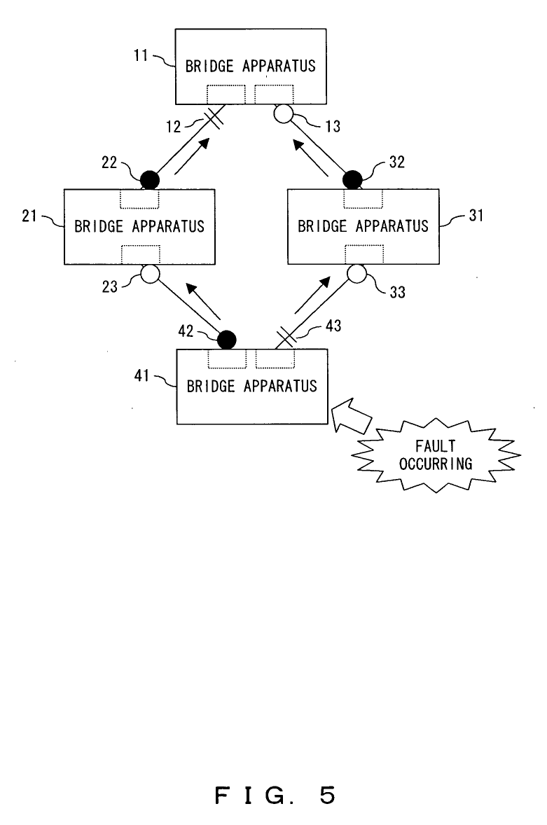

If, however, the spanning tree protocol becomes inoperable in the bridge apparatus 41 having the port (i.e., alternate port) 43 in the blocking state like the bridge apparatus 41 as shown by FIG. 1A in the normal state for instance, assuming that the bridge apparatus 41 has the function of the above described bridge apparatus 100, then the topology will be restructured to a form as shown by FIG. 5, creating a point being unnecessarily blocked (i.e., the port (i.e., alternate port) 12 of the bridge apparatus 11), hence bringing forth a possibility of disabling communication between some bridge apparatuses (i.e., between the bridge apparatuses 11 and 41).

Accordingly, each of the bridge apparatuses 11, 21, 31 and 41 is furnished with a function to transmit a BPDU only from ports in the state of forwarding, instead of transmitting from ports in the state of non-forwarding, in order to avoid the occurrence of such a problem.

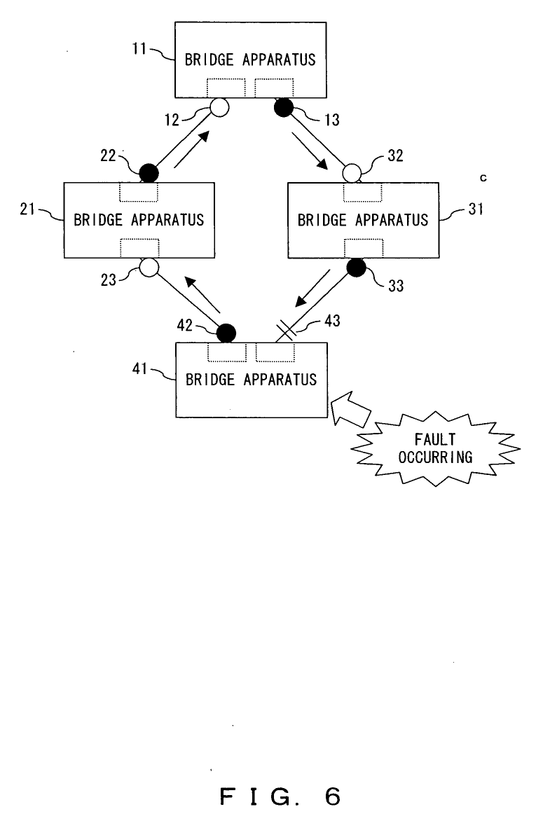

As a result, a normal topology will be restructured as shown by FIG. 6, if the spanning tree protocol becomes inoperable in the bridge apparatus 41 having a port (i.e., alternate port) 43 in the state of blocking in the normal state such as the bridge apparatus 41 as shown by FIG. 1A.

Also, each of the bridge apparatuses 11, 21, 31 and 41 is furnished with a function for changing the state of all ports in the state of non-forwarding to that of forwarding so as to transmit BPDUs from all the ports for another countermeasure to avoid an occurrence of the problem as described above.

As a result, a normal topology will be restructured as shown by FIG. 6, if the spanning tree protocol becomes inoperable in the bridge apparatus 41 having a port (i.e., alternate port) 43 in the state of blocking in the normal state such as the bridge apparatus 41 as shown by FIG. 1A.

Furthermore, it is possible to shorten the time to reopen communication through a new topology by proactively erasing the MAC learning table 105 when restructuring the topology applied by the present invention. The bridge apparatus 100 shown by FIG. 3 determines the relationship between the source MAC address of the input Ethernet frame and the input port in advance, and decides on an output port for the Ethernet frame based on the MAC learning table created as a result of the aforementioned determination. Consequently, there is a possibility that an actual communication is unable to keep track of a topology change if it is made before the MAC learning table 105 goes through aging (for a few minutes usually).

Accordingly, the countermeasure is to have the bridge apparatus 100 in which the spanning tree protocol has become inoperable erase the MAC learning table 105, thereby shortening the time to reopen communication.

Also, have other bridge apparatuses erase the MAC learning tables by setting up a TC (Topology Change) flag for a certain length of time (or during the time of the spanning tree protocol being inoperable) for the BPDU which is transmitted at the time of the spanning tree protocol becoming inoperable, thereby shortening the time to reopen communication.

It is also possible to remove a need to set up a TC flag in a BPDU transmitted from the bridge apparatus in which the spanning tree protocol has become inoperable by letting the adjacent bridge apparatus erase the MAC learning table at the time of receiving a BPDU having a Root ID of a predetermined value (e.g., All bits “0”).

Incidentally, there is a possibility of functioning abnormally due to the existence of two or more bridge apparatuses in the network in which the spanning tree protocol becomes inoperable simultaneously. If, however, a second bridge apparatus transmits a Root ID of a predetermined value (e.g., All bits “0”), all the ports can be blocked as in the conventional technique.

The next description is of the preferred embodiments applied by the present invention in further detail.

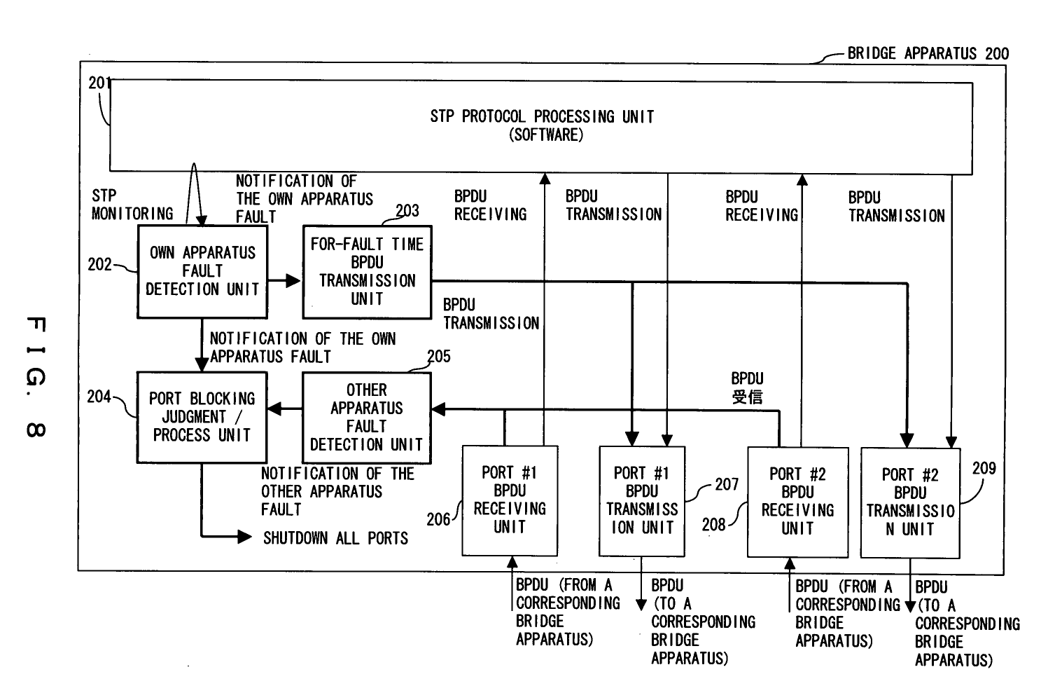

FIG. 8 shows a comprisal of a first embodiment of the present invention applied to a bridge apparatus.

In FIG. 8, the bridge apparatus 200 comprises an STP protocol processing unit 201, an internal fault detection unit 202, a for-fault time BPDU transmission unit 203, a port blocking judgment/process unit 204, an external apparatus fault detection unit 205, a port #1 BPDU receiving unit 206, a port #1 BPDU transmission unit 207, a port #2 BPDU receiving unit 208 and a port #2 BPDU transmission unit 209.

The following description is of an operation of such a comprised bridge apparatus 200 in the state of no occurrence of fault, or disability of operation.

A BPDU received at the port #1 from an adjacent bridge apparatus is transferred to the STP protocol processing unit 201 by way of the port #1 BPDU receiving unit 206. Likewise, a BPDU received at the port #2 from an adjacent bridge apparatus is then transferred to the STP protocol processing unit 201 by way of the port #2 BPDU receiving unit 208.

Consequently, the STP protocol processing unit 201 transmits a BPDU which is set up with appropriate data to a suitable port based on the information contained by the received BPDU.

In this event, the operation is in the state of no fault or disability of operation, neither the internal fault detection unit 202 nor the external apparatus fault detection unit 205 ever detects a fault or a disability of operation. Therefore, neither the for-fault time BPDU transmission unit 203 nor the port blocking judgment/process unit 204 operates, nor will a for-fault time BPDU be transmitted to an adjacent bridge apparatus by way of the port #1 BPDU transmission unit 207 or the port #2 BPDU transmission unit 209. Nor will all Ports be shutdown.

The next description is of a processing sequence for the case in which the state changed from the above described no fault or disability of operation to the STP protocol processing unit 201 becoming inoperable within the bridge apparatus 200 per se (i.e., apparatus itself) due to either a fault, a disability of operation or a software update; and another for the case in which the bridge apparatus 200 (i.e., apparatus itself) recovering from its internal fault or disability of operation.

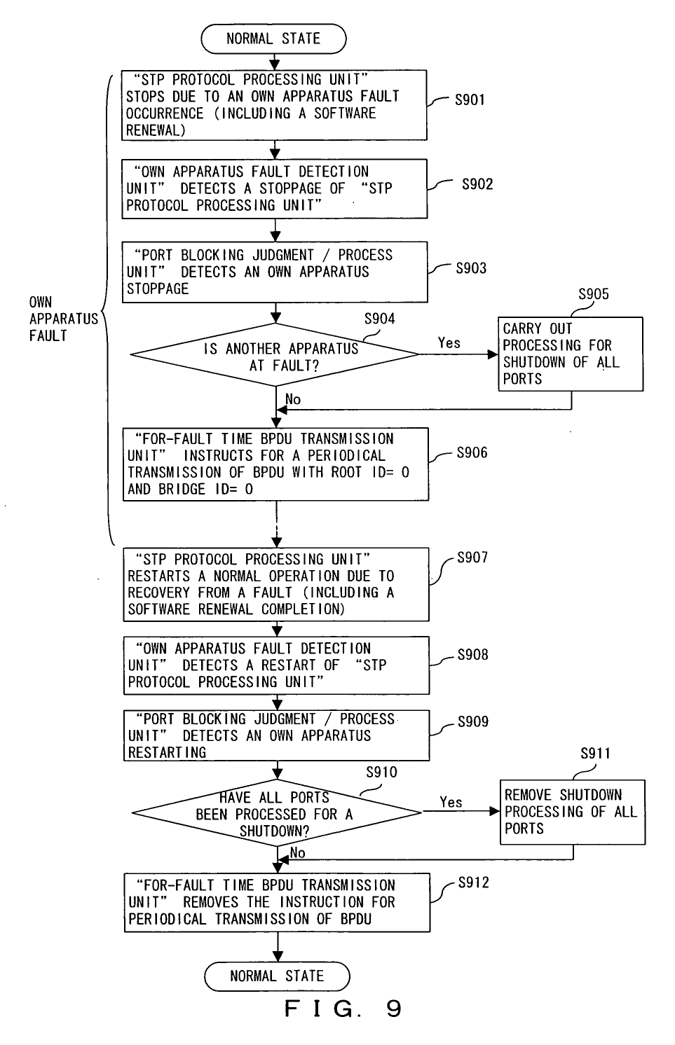

FIG. 9 shows a processing sequence from a fault, or a disability of operation, to recovery in the apparatus itself.

As a fault or a disability of operation (including a software update) occurs from the normal state in the bridge apparatus 200 (i.e., apparatus itself), the STP protocol processing unit 201 stops (step S901) (simply “step 901” hereinafter) . Then, the internal fault detection unit 202 monitoring the STP protocol processing unit 201 detects the stoppage thereof (step 902), and the port blocking judgment/process unit 204 detects the stoppage of the bridge apparatus 200 (i.e., apparatus itself) by having received a notification of “STP protocol processing unit 201 stopping” from the internal fault detection unit 202 (step 903).

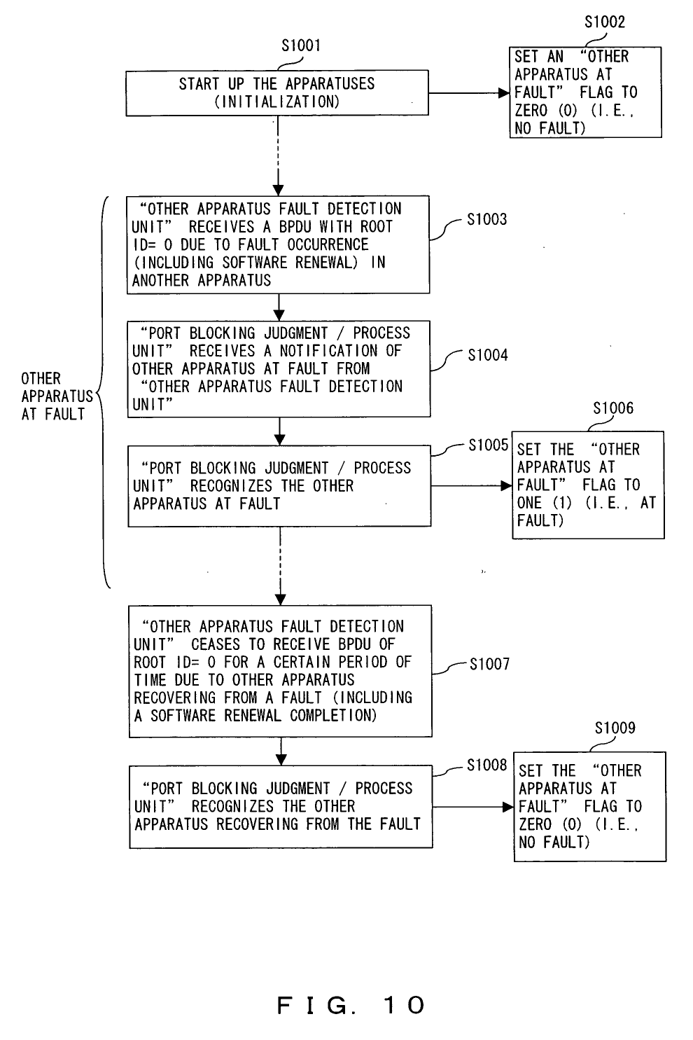

Then, the other apparatus fault detection unit 205, which has received a BPDU from a corresponding other bridge apparatus by way of either the port #1 BPDU receiving unit 206 or port #2 BPDU receiving unit 208, judges whether or not a fault or a disability of operation has occurred in the other bridge apparatuses (i.e., other apparatus) (step 904). Note that a detail of judgment for a fault or a disability of operation in external bridge apparatus (i.e., external apparatus) will be described later in association with FIG. 10.

If the judgment is that a fault or a disability of operation has occurred in external bridge apparatus (i.e., external apparatus) (“yes” for step 904), the processing is to shutdown all the ports of all the bridge apparatuses constituting the network to sever all the connections with other bridge apparatuses (step 905), thereby making it possible to prevent the spanning tree protocol from becoming unstable in the entire network.

Then, the for-fault time BPDU transmission unit 203 transmits a BPDU set up with “Root ID=0 and Bridge ID=0” to the adjacent bridge apparatuses (i.e., other apparatus) periodically (step 906). Consequently, the adjacent other bridge apparatus (i.e., adjacent bridge apparatus) receives the BPDU and then relays it to the next adjacent bridge apparatus, hence propagating the information of Root ID=0, thereby enabling all the other bridge apparatuses (i.e., other apparatuses) within the network to recognize the bridge apparatus 200 as the root bridge apparatus.

Subsequently, when the bridge apparatus 200 (i.e., apparatus itself) recovers from a fault or a disability of operation (including a software update), the STP protocol processing unit 201 restarts operating normally, performing transmissions of BPDUs by way of the port #1 BPDU transmission unit 207 and port #2 BPDU transmission unit 209 once again (step 907). Accordingly, the internal fault detection unit 202 monitoring the STP protocol processing unit 201 detects the restart thereof (step 908), and the port blocking judgment/process unit 204 detects the restart of the bridge apparatus 200 (i.e., apparatus itself) by having received a notification of “STP protocol processing unit 201 restarting” from the internal fault detection unit 202 (step 909), followed by judging whether or not all the ports of all the bridge apparatus have been processed for a shutdown (step 910).

If the judgment is “shutdown” (“yes” for step 910), the processing is to negate the shutdown for all the ports of all the bridge apparatuses constituting the network to reestablish the interconnection between all the adjacent bridge apparatuses (step 911), hence recovering to the original normal state.

Next, the for-fault time BPDU transmission unit 203 removes the instruction for a periodical transmission of BPDU which has been put in practice (i.e., a periodical transmission of BPDU set up with “Root ID=0 and Bridge ID=0” to the adjacent other bridge apparatus (i.e., other apparatus)) (step 912). As a result, the instruction for transmitting a BPDU of Root ID=0 carried out by the for-fault time BPDU transmission unit 203 will be stopped, resulting in the BPDU to be transmitted from the bridge apparatus 200 becoming only as per the instruction from the STP protocol processing unit 201, hence recovering to the normal state.

Note, however, that the above described operation at the time of fault or disability of operation, or at the time of recovering from the fault or disability of operation, assumes there is no such fault or disability of operation having occurred in the other bridge apparatuses. If, however, the same operation as described above is performed when there is a fault or disability of operation in another bridge apparatus, there will be a plurality of root bridge apparatuses which transmit the BPDUs of Root ID=0 within the network, negating the uniqueness of the root bridge apparatus, hence making it possible to cause the spanning tree protocol to be unstable. Therefore, when receiving a BPDU of Root ID=0, it is necessary to recognize that there is a fault or a disability of operation in another bridge apparatus.

FIG. 10 shows a processing sequence from a fault, or a disability of operation, to a recovery in another apparatus.

First, the initialization is to start the bridge apparatuses 200 (step 1001), followed by setting an “other apparatus at fault” flag to zero (0) (i.e., no fault or a disability of operation) (step 1002).

Then, the other apparatus fault detection unit 205 receives a BPDU sent from another bridge apparatus by way of the port #1 BPDU receiving unit 206 and port #2 BPDU receiving unit 208, and containing information of Root ID=0 which indicates that there is a fault or a disability of operation including a software update in another bridge apparatus (step 1003).

And the port blocking judgment/process unit 204 receives the information about the fault or disability of operation including a software update occurring in the other bridge apparatus (step 1004), recognizes the fault or disability of operation including a software update occurring in the other bridge apparatus (step 1005) and sets the “other apparatus at fault” flag to one (1) (i.e., there is a fault or a disability of operation) (step 1006). The recognition in the step 1005 will be used for the judgment of the step 904 shown by FIG. 9.

Then, as the other apparatus fault detection unit 205 detects the fact of not receiving, for a certain period of time, the BPDU containing the information of Root ID=0 which indicates that there is a fault or a disability of operation including a software update in the other bridge apparatus (step 1007), the port blocking judgment/process unit 204 recognizes that the other bridge apparatus has recovered from the fault or the disability of operation (step 1008), and changes the “other apparatus at fault” flag to zero (0) (i.e., no fault or disability of operation) (step 1009). The recognition in the step 1008 will also be used for the judgment of the step 904 shown by FIG. 9.

While the preferred embodiment has so far been described, the application of the present invention to a bridge apparatus is not limited to the above described embodiment, but other forms may of course be adopted as far as the function is carried out, such as a single apparatus, a system or integrated apparatus comprising a plurality of apparatuses, or a system performing processing by way of a network such as a LAN or WAN.

Alternatively, the application of the present invention to a bridge apparatus can be accomplished by a system comprising a CPU 1101, memory 1102 such as ROM or RAM, an input apparatus 1103, an output apparatus 1104, an external storage apparatus 1105, a media drive apparatus 1106, a portable storage apparatus 1110 and a network connection apparatus 1107 with a bus 1109 interconnecting the aforementioned components. That is, it is obvious that application of the present invention to the bridge apparatus can be accomplished by furnishing the memory 1102 such as ROM or RAM, external storage apparatus 1105 and portable storage medium 1110 which store the program code of the software accomplishing the system of the above described embodiment to the bridge apparatus so that the computer comprised thereby reads out the program code for execution.

In such a case, the program code itself read out of the portable storage medium 1110, et cetera, accomplishes the novel function of the present invention, and therefore the portable storage medium 1110, etcetera, comprises the present invention.

The portable storage media 1110 for supplying the program code can utilize flexible disk, hard disk, optical disk, magneto optical disk, CD-ROM, CD-R, DVD-ROM, DVD-RAM, magnetic tape, non-volatile memory, ROM card, various storage media storing by way of network connection apparatus 1107 such as e-mail, PC communication, et cetera, for example.

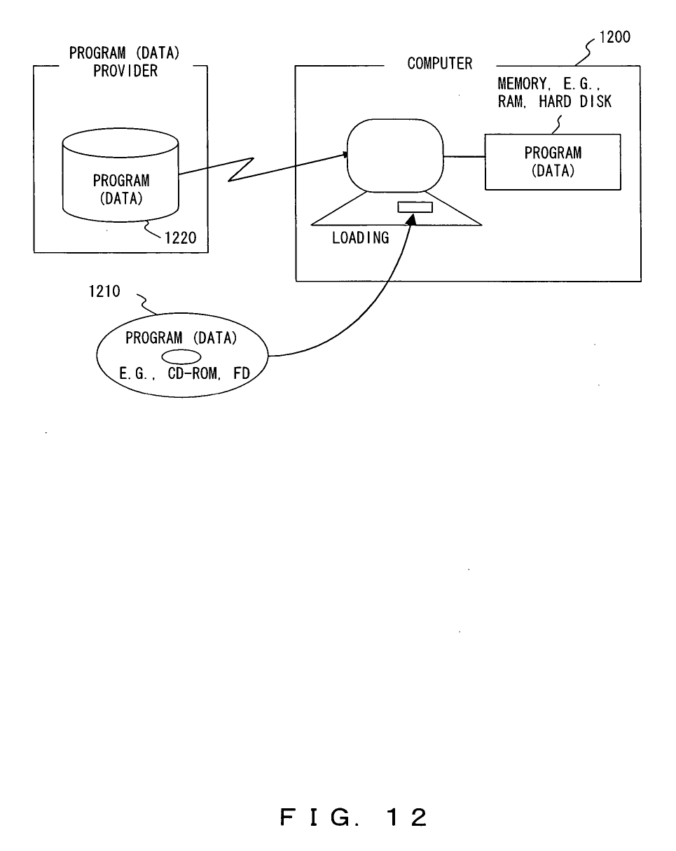

Also, the above described function of the present embodiment is accomplished by a computer (i.e., information processing apparatus) 1200 executing the program code read out into memory 1201 as shown by FIG. 12, and in addition, by an OS (operating system) operating in the computer executing a part or all of the actual processing.

Furthermore, the above described functionality of the present embodiment will be accomplished by a program code read out of a portable storage medium 1210, or a program (data) provided by a program (data) provider, being written in memory 1202 comprised by a function expansion board inserted into the computer 1200 or a function expansion unit connected therewith, followed by a CPU, et cetera, comprised by the function expansion board or the function expansion unit executing a part or all of the actual processing.

The present invention enables a bridge apparatus supporting a spanning tree protocol to continue all communications even if a fault, a disability of operation or a software update occurs therein, causing the spanning tree protocol to become inoperable and, furthermore, provides a network capable of keeping track of status changes thereof.

What is claimed is:

1. A bridge apparatus, in the bridge apparatus constituting a network by connecting with other bridge apparatus, comprising:
an STP protocol processing unit for carrying out a spanning tree protocol;
a port for transmitting and receiving a bridge protocol data unit with the other bridge apparatus;
a fault detection unit for detecting a fault, or a disability of operation, of the spanning tree protocol by monitoring the STP protocol processing unit; and
a for-fault time BPDU transmission unit for transmitting a for-fault time bridge protocol data unit to the other bridge apparatus by way of the port if the fault detection unit detects a fault, or a disability of operation, of the spanning tree protocol.

2. The bridge apparatus according to claim 1, wherein a for-fault time bridge protocol data unit transmitted by said for-fault time BPDU transmission unit has a smaller valued route identifier than a route identifier possessed by said other bridge apparatus.

3. The bridge apparatus according to claim 2, wherein a for-fault time bridge protocol data unit transmitted by said for-fault time BPDU transmission unit has a route identifier whose value is zero (0).

4. The bridge apparatus according to claim 1, wherein said for-fault time BPDU transmission unit transmits said for-fault time bridge protocol data unit to said other bridge apparatus by way of all ports being in a state of forwarding.

5. The bridge apparatus according to claim 1, wherein said for-fault time BPDU transmission unit transmits said for-fault time bridge protocol data unit to the other bridge apparatus by way of all ports, and the ports reset a state of non-forwarding to a state of forwarding.

6. The bridge apparatus according to claim 1, wherein said fault detection unit erases data in a MAC learning table recording a MAC address after detecting a fault or, a disability of operation, of said spanning tree protocol.

7. The bridge apparatus according to claim 6, wherein said fault detection unit ceases to carry out writing in said MAC learning table for a certain period of time after erasing data in the MAC learning table.

8. The bridge apparatus according to claim 1, wherein said port sets a topology change flag of a transmitting bridge protocol data unit to “on” for a predetermined period of time if said fault detection unit detects a fault, or a disability of operation, of said spanning tree protocol.

9. The bridge apparatus according to claim 1, wherein said fault detection unit erases data in a MAC learning table recording a MAC address if said port receives a bridge protocol data unit having a topology change flag which is set to “on”.

10. The bridge apparatus according to claim 1, wherein said fault detection unit erases data in a MAC learning table recording a MAC address if said port receives a bridge protocol data unit having a root identifier of a predetermined value.

11. The bridge apparatus according to claim 10, wherein said fault detection unit erases data in a MAC learning table recording a MAC address if said port receives a bridge protocol data unit having a root identifier whose value is set to zero (0).

12. The bridge apparatus according to claim 1, wherein said for-fault time BPDU transmission unit inhibits itself from transmitting said for-fault time bridge protocol data unit to said other bridge apparatus if said fault detection unit detects a fault, or a disability of operation, of said spanning tree protocol and if said port receives a bridge protocol data unit having a root identifier which is set to a predetermined value.

13. A control packet processing method carried out by a bridge apparatus comprising an STP protocol processing unit for carrying out a spanning tree protocol, and a port for transmitting and receiving a bridge protocol data unit with another bridge apparatus; and constituting a network by connecting with other bridge apparatus, comprising the steps of
detecting a fault, or a disability of operation, of the spanning tree protocol by monitoring the STP protocol processing unit; and
transmitting a for-fault time bridge protocol data unit to the other bridge apparatus by way of the port if detecting a fault, or a disability of operation, of the spanning tree protocol.

14. A computer executable control packet processing program, which is to be executed by a bridge apparatus comprising an STP protocol processing unit for carrying out a spanning tree protocol, and a port for transmitting and receiving a bridge protocol data unit with another bridge apparatus; and constituting a network by connecting with other bridge apparatus, comprising the procedures of
detecting a fault, or a disability of operation, of the spanning tree protocol by monitoring the STP protocol processing unit; and
transmitting a for-fault time bridge protocol data unit to the other bridge apparatus by way of the port if detecting a fault, or a disability of operation, of the spanning tree protocol.
